(19) United States
(12) Patent Application Publication
(10) Pub. No.: US 2026/0068776 A1
(43) Pub. Date: Mar. 5, 2026

(54) ELECTRONIC MODULE AND METHOD OF MANUFACTURING THE SAME

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventors: Jia-Hui WANG, Hebei Province (CN); Yuan-Yu LIN, Hebei Province (CN); Yue LIU, Hebei Province (CN); Lingyu GUO, Hebei Province (CN)

(21) Appl. No.: 18/818,161

(22) Filed: Aug. 28, 2024

(51) Int. Cl. H01L 23/498; H05K 1/18

(52) U.S. Cl. CPC H01L 23/49816; H05K 1/189; H05K 2201/10734

(57) ABSTRACT

An electronic module and a method of manufacturing the same are provided. The electronic module includes an interposer, a first electronic component, a flexible circuit board, and a second electronic component. The interposer includes a Redistribution Layer (RDL), and a main body layer. The main body layer is disposed on the RDL and has a recess exposing the RDL. The first electronic component is embedded in the recess of the interposer and electrically connected with the RDL. The flexible circuit board wraps the interposer and the first electronic component. The second electronic component is disposed on the flexible circuit board and overlaps the first electronic component.

### BACKGROUND

### Field of Invention The present disclosure relates to an electronic module and a manufacturing method thereof.

### Description of Related Art

An existing memory, such as High Bandwidth Memory (hereinafter HBM), is usually made by vertical assembly. However, the existing Graphics Processing Unit (hereinafter GPU) has complex circuit layouts and memory interfaces, so that the HBM cannot be directly assembled vertically with the GPU, that is, it is hard to assemble GPU and HBM together in a stack. Therefore, currently, the GPU and the HBM are usually mounted on the same side of one base board to form an electronic module. When the electronic module is mounted on the circuit board, the electronic module will occupy a larger area on the circuit board, thereby limiting the number of components that can be mounted on the circuit board. Thus, it is disadvantageous to develop mobile devices (such as mobile phones and tablet computers) towards the current trend in multi-function and reducing size.

### SUMMARY

At least one embodiment of the present disclosure provides an electronic module and a manufacturing method thereof to overlap and assemble a HBM and a GPU, thereby significantly reducing the area occupied by the electronic module on the circuit board and increasing the number of components that can be disposed on the circuit board.

At least one embodiment of the present disclosure provides an electronic module including an interposer, a first electronic component, a flexible circuit board and a second electronic component. The interposer includes a redistribution layer and a main body layer. The main body layer is disposed on the redistribution layer and has a recess exposing the redistribution layer. The first electronic component is embedded in the recess of the interposer and is electrically connected to the redistribution layer. The flexible circuit board covers the interposer and the first electronic component. The second electronic component is disposed on the flexible circuit board and overlaps the first electronic component.

At least one embodiment of the present disclosure provides a method of manufacturing the electronic module including providing an interposer; embedding a first electronic component into the interposer; covering a flexible circuit board on the interposer after the first electronic component has been embedded; and after the flexible circuit board covers the interposer, a second electronic component is disposed on the flexible circuit board, wherein the first electronic component overlaps the second electronic component.

According to the above description, the above-mentioned flexible circuit board can replace the semiconductor base board, so that the first electronic component and the second electronic component can overlap and be vertically assembled, thus greatly reducing the occupied area of the electronic module on the circuit board and further increasing the number of components that can be disposed on the board for the development of the trend in multi-function and reducing size.

### BRIEF DESCRIPTION OF THE DRAWINGS

The disclosure can be more fully understood by reading the following detailed description of the embodiment, with reference made to the accompanying drawings as follows:

FIG. 1 illustrates a cross-section schematic diagram of an electronic module according to an embodiment of the present disclosure.

FIG. 2A to FIG. 2C illustrate cross-section schematic diagrams of a method of manufacturing the electronic module according to FIG. 1.

### DETAILED DESCRIPTION

It is to be understood that the following disclosure provides many different embodiments or examples for implementing different elements of the provided subject matter. Specific examples of each element and its arrangement are described below in order to simplify the description of the disclosed content. Of course, these are only examples and are not intended to limit the present embodiments. For example, the size of an element is not limited to the range or value of an embodiment of the present disclosure, but may depend on the processing conditions and/or required properties of the component. Furthermore, in the subsequent description above the second component or the first component formed on the second component covers embodiments in which the first and second components are in direct contact, and embodiments in which additional components are formed between the first and second components so that the first and second components are in partial direct contact are also covered. In addition, repeated reference symbols and/or words may be used in different examples of the disclosure. These repeated symbols or words are for the purpose of simplicity and clarity, and are not used to limit the relationship between the various embodiments and/or the described appearance structures.

It should be understood that although the disclosure can use the terms herein that a first, a second, a third etc. to describe various elements, components, regions, layers or sections. But these elements, components, regions, layers or sections are not limited in the disclosure. In addition, these terms are only used to distinguish one element, component, region, layer or section from another element, component, region, layer or section. Thus, a first element, component, region, layer or section discussed below could be termed a second element, component, region, layer or section without departing form the conceptual teachings of the present disclosure.

In the following text, in order to clearly present the technical features of this case, the dimensions (such as length, width, thickness and depth) of the components (such as layers, electrodes, base boards, regions, etc.) in the drawings are expressed in unequal proportions to be enlarged, and the number of some components will be reduced. Therefore, the description and explanation of the embodiments below are not limited to the number of components and the sizes and shapes of the components in the drawings, but should cover the size, shape, and deviations in both caused by actual manufacturing processes and/or tolerances. For example, regions shown or described as flat may typically have rough and/or non-linear characteristics. Additionally, the acute angles shown may be rounded. Therefore, the components shown in the drawings of this case are mainly for illustration, and are not intended to accurately depict the actual shapes of the components, nor are they intended to limit the patent scope of this case.

Furthermore, when an element such as a layer, film, region, or base board is referred to as being “on” or “connected to” another element, it can be directly on or connected to the other element, or intermediate elements may also be present. In contrast, when an element is referred to as being “directly on” or “directly connected to” another element, there are no intervening elements present. As used herein, “connection” may only be physical and/or electrical connection. Furthermore, “electrical connection” can be the presence of other components between the two components.

Moreover, relative terms such as “lower” or “bottom: and “upper” or “above” may be used herein to describe the relationship of one element between another element as illustrated in the figures. It will be understood that relative terms are intended to encompass different orientations of the device in addition to the orientation illustrated in the figures. For example, if the device in one of the figures is turned over, elements described as “lower” than other elements would then be oriented on the “upper” side if the other elements. Thus, the exemplary term “lower” may include bother “lower” and “upper” orientations, depending on the particular orientation of the drawing. Similarly, if the device in one of the figures is turned over, elements described as “below” other elements would then be oriented “above” the other elements. Thus, the exemplary term “below”may include both upper and lower orientations.

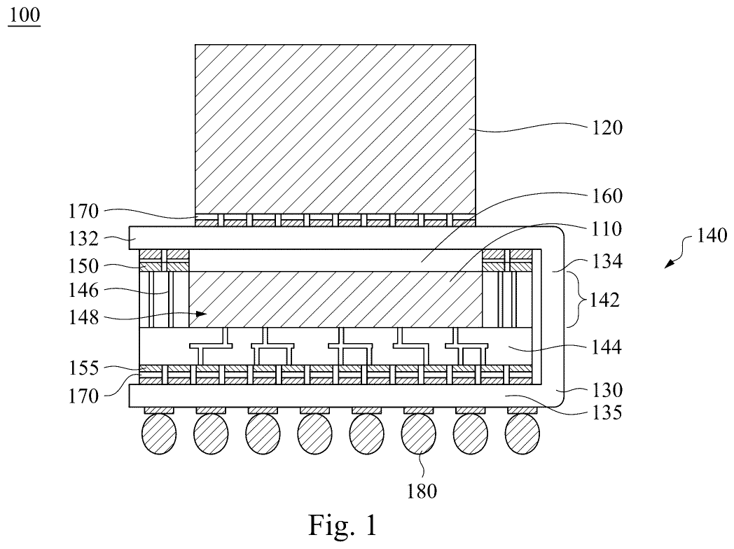

FIG. 1 is illustrates a cross-section schematic diagram of an electronic module 100 according to at least one embodiment of the present disclosure. Referring to FIG. 1, the electronic module 100 includes an interposer 140, a first electronic component 110, a flexible circuit board 130 and a second electronic component 120. The interposer 140 includes a redistribution layer 144 and a main body layer 142. The main body layer 142 is disposed on the redistribution layer 144 and has a recess 148 exposing the redistribution layer 144. The first electronic component 110 is embedded in the recess 148 of the interposer 140 and is electrically connected to the redistribution layer 144. The flexible circuit board 130 wraps the interposer 140 and the first electronic component 110. The second electronic component 120 is disposed on the flexible circuit board 130 and overlaps the first electronic component 110.

The first electronic component 110 and the second electronic component 120 may be logic devices and memories. For example, the first electronic component 110 may be Central Processing Unit (CPU) or Graphics Processing Unit (GPU). The second electronic component 120 may be Dynamic Random Access Memory (DRAM), flash memory or High Bandwidth Memory (HBM). In some embodiments, each of the first electronic component 110 and the second electronic component 120 can be the same type of device (e.g., System on a Chip, SoC).

In this embodiment, the first electronic component 110 is embedded in the interposer 140 and electrically connected to the redistribution layer 144, and the flexible circuit board 130 is used to cover the interposer 140, so as to redistribute and extend the circuits. As a result, even though the first electronic component 110 (such as GPU) has complex circuit layouts and memory interfaces, the second electronic component 120 and the first electronic component 110 can be vertically assembled by using the interposer 140 and the flexible circuit board 130.

The flexible circuit board 130 can be bent into a U-shape to cover the first electronic component 110 and the interposer 140. Specifically, the bent flexible circuit board 130 includes a first sub-board 132, a second sub-board 134 and a third sub-board 135. The first sub-board 132 is sandwiched between the second electronic component 120 and the interposer 140. The second sub-board 134 covers one side of the interposer 140 and is connected to the first sub-board 132. The third sub-board 135 covers the redistribution layer 144 and is connected to the second sub-board 134, where the interposer 140 is located between the first sub-board 132 and the third sub-board 135, and the second sub-board 134 is connected between the first sub-board 132 and the third sub-board 135.

In the embodiment shown in FIG. 1, the first sub-board 132 and the third sub-board 135 cover the upper surface and the lower surface of the interposer 140 respectively, while the second sub-board 134 covers a part of the side of the interposer 140, but the other part of the side of the interposer 140 are not covered, that is, the flexible circuit board 130 partially exposes the side of the interposer 140. It should be noted that the side surface of the interposer 140 is in the shape of a ring. In addition, in some embodiments, the flexible circuit board 130 can also be bent and wrapped into an O-shape to surround the interposer 140, in which the flexible circuit board 130 wrapped into the O-shape covers two opposite parts of the side of the interposer 140.

The interposer 140 includes a plurality of first pads 150 which are disposed on the main body layer 142 and located between the main body layer 142 and the first sub-board 132. These first pads 150 are electrically connected between the main body layer 142 and the first sub-board 132. There are also a plurality of second pads 155 disposed on the redistribution layer 144 and located between the redistribution layer 144 and the third sub-board 135, in which these second pads 155 are electrically connected to the redistribution layer 144 and the third sub-board 135.

The interposer 140 further includes a plurality of Through-Silicon Vias (hereinafter TSVs) 146, and these TSVs 146 are disposed in the main body layer 142 and connected to the redistribution layer 144. The material of the interposer 140 may be silicon or glass, that is, the interposer 140 may be made of silicon or glass, so the material of the through-hole in the interposer 140 is not limited to TSV 146 or Through-Glass Via (TGV).

The redistribution layer (RDL) 144 is a composite layer including a metal layer and an insulating layer. The material of the metal layer can be copper, and the material of the insulating layer can be an inorganic insulating material (such as at least two of silicon dioxide and silicon nitride) or organic insulating materials (such as polyimide, PI). Alternatively, the material of the above-mentioned insulating layer can include organic insulating material and inorganic insulating material.

The filling colloid 160 is disposed between the first sub-board 132 and the first electronic component 110 of the flexible circuit board 130. The filling colloid 160 can be an organic composite material, a resin composite material, or a polymer composite material, such as a sealing compound or an epoxy with filler.

The solders 180 connected to the third sub-board 135, and the third sub-board 135 is located between the solders 180 and the interposer 140. The solder 180 can be formed by such as printing, solder transfer, or similar methods. Once the solder layer is formed in the structure, reflow can be performed.

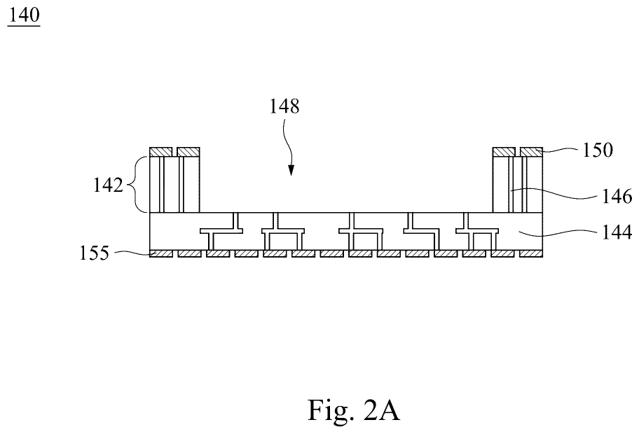

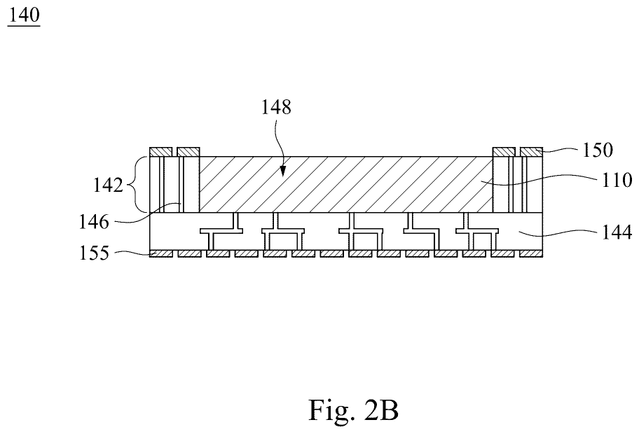

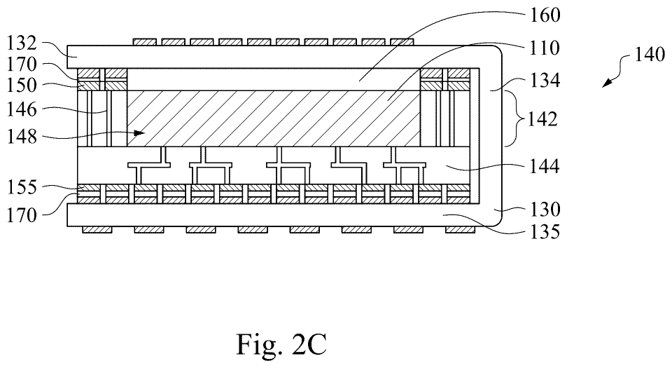

FIG. 2A to FIG. 2C illustrate cross-section schematic diagrams of a method of manufacturing the electronic module according to FIG. 1. Referring to FIG. 2A, in the manufacturing method of electronic module 100, first, an interposer 140 is provided.

Referring to FIG. 2B, then, a first electronic component 110 is embedded into the interposer 140, and a flexible circuit board 130 wraps the interposer 140 after the first electronic component 110 is embedded.

Referring to FIG. 2C, after the flexible circuit board 130 covers the interposer 140, a second electronic component 120 is disposed on the flexible circuit board 130, where the first electronic component 110 overlaps the second electronic component 120. Before disposing the second electronic component 120 on the flexible circuit board 130, a filling colloid 160 is disposed on the first electronic component 110, where the flexible circuit board 130 covers the filling colloid 160. The interposer 140 has a recess 148 for disposing the electronic component, and the thickness of the first electronic component 110 is less than the depth of the recess 148.

The conductive connection material 170 may include solder, tin, copper, gold, nickel, or silver glue, or alloys. In other embodiments, the second electronic component 120 can be connected to the flexible circuit board 130 by direct bonding, such as eutectic bonding, so that the underfill can be omitted.

Consequently, in the electronic module 100 of at least one embodiment of the present disclosure, the above-mentioned flexible circuit board 130 can replace the semiconductor base board, so that the first electronic component 110 (such as GPU) and the second electronic component 120 (such as HBM) overlap and are vertically assembled, thus greatly reducing the occupied area by the electronic module 110 on the circuit board and increasing the number of components that can be disposed on the board for the development of the trend in multi-function and reducing size.

Although the present application has been disclosed d in various embodiments as above, it is not intended to limit the present application. The components of several embodiments are summarized above so that those with PHOSITA to which the present disclosure belongs can more easily understand the opinion of the embodiments. Those PHOSITA of the present disclosure should understand that they can design or modify other processes and structures based on the embodiments of the present disclosure to achieve the same purposes and/or advantages as the embodiments introduced here. Those PHOSITA to which the present disclosure belongs should also understand that such equivalent processes and structures do not deviate from the spirit and scope of the present disclosure, and they can be used, various changes, substitutions and substitutions are made, without departing from the spirit and scope of the present disclosure. So the protection scope of this application shall be determined by the appended patent application scope. Although the present invention has been described in considerable detail with reference to certain embodiments thereof, other embodiments are possible. Therefore, the spirit and scope of the appended claims should not be limited to the description of the embodiments contained herein.

What is claimed is:

1. An electronic module, comprising:
an interposer, comprising:
a redistribution layer;
a main body layer, disposed on the redistribution layer and having a recess exposing the redistribution layer;
a first electronic component, embedded in the recess of the interposer and electrically connected with the redistribution layer;
a flexible circuit board, wrapping the interposer and the first electronic component; and
a second electronic component, disposed on the flexible circuit board, and overlapping the first electronic component.

2. The electronic module of claim 1, wherein the flexible circuit board, comprising:
a first sub-board, sandwiched between the second electronic component and the interposer;
a second sub-board, covering a side of the interposer and connected with the first sub-board; and
a third sub-board, covering the redistribution layer and connected with the second sub-board, wherein the interposer is located between the first sub-board and the third sub-board, and the second sub-board is connected between the first sub-board and the third sub-board.

3. The electronic module of claim 2, further comprising:
a plurality of solders, connected with the third sub-board, and the third sub-board located between these solders and the interposer.

4. The electronic module of claim 2, wherein the interposer further comprises:
a plurality of first pads, disposed on the main body layer and located between the main body layer and the first sub-board, wherein the plurality of first pads are electrically connected between the main body layer and the first sub-board; and
a plurality of second pads, disposed on the redistribution layer and located between the redistribution layer and the third sub-board, wherein the plurality of second pads are electrically connected between the redistribution layer and the third sub-board.

5. The electronic module of claim 2, further comprising:
a plurality of solders, connected with the third sub-board, and the third sub-board located between these solders and the interposer, wherein the interposer further comprises:
a plurality of first pads, disposed on the main body layer and located between the main body layer and the first sub-board, wherein the plurality of first pads are electrically connected between the main body layer and the first sub-board; and
a plurality of second pads, disposed on the redistribution layer and located between the redistribution layer and the third sub-board, wherein the plurality of second pads are electrically connected between the redistribution layer and the third sub-board.

6. The electronic module of claim 1, wherein the first electronic component is a graphics processing unit, and the second electronic component is a high bandwidth memory.

7. The electronic module of claim 1, wherein the interposer further comprises a plurality of through-silicon vias, and the plurality of through-silicon vias are disposed in the main body layer and connected to the redistribution layer.

8. The electronic module of claim 1, wherein the first electronic component is a graphics processing unit, and the second electronic component is a high bandwidth memory,
wherein the interposer further comprises a plurality of through-silicon vias, and the plurality of through-silicon vias are disposed in the main body layer and connected to the redistribution layer.

9. The electronic module of claim 2, further comprising:
a filling colloid, disposed between the first sub-board and the first electronic component of the flexible circuit board.

10. The electronic module of claim 2, wherein the first electronic component is a graphics processing unit, and the second electronic component is a high bandwidth memory.

11. The electronic module of claim 2, wherein the interposer further comprises a plurality of through-silicon vias, and the plurality of through-silicon vias are disposed in the main body layer and connected to the redistribution layer.

12. A method, comprising:
providing an interposer;
embedding a first electronic component into the interposer;
wrapping the interposer with a flexible circuit board after the first electronic component is embedded into the interposer; and
after the flexible circuit board wraps the interposer, a second electronic component is disposed on the flexible circuit board, wherein the first electronic component overlaps the second electronic component.

13. The method of claim 12, further comprising:
before disposing the second electronic component on the flexible circuit board, disposing a filling colloid on the first electronic component, wherein the flexible circuit board covers the filling colloid.

14. The method of claim 12, wherein the interposer has a recess for disposing the electronic component, and a thickness of the first electronic component is less than a depth of the recess.

15. The method of claim 12, further comprising:
before disposing the second electronic component on the flexible circuit board, disposing a filling colloid on the first electronic component, wherein the flexible circuit board covers the filling colloid,
wherein the interposer has a recess for disposing the electronic component, and a thickness of the first electronic component is less than a depth of the recess.
